(19) United States
(12) Patent Application Publication
(10) Pub. No.: US 2011/0121305 A1
(43) Pub. Date: May 26, 2011

(54) THIN FILM TRANSISTOR DEVICE AND METHOD OF MAKING THE SAME

(76) Inventor: Cheng-Chieh Tseng, Hsin-Chu (TW)

(21) Appl. No.: 12/693,457

(22) Filed: Jan. 26, 2010

(30) Foreign Application Priority Data
Nov. 20, 2009 (TW) 098139510

(51) Int. Cl. H01L 29/04; H01L 29/786; H01L 21/336; H01L 21/20

(52) U.S. Cl. 257/66; 438/151; 438/479; 257/E29.003; 257/E29.273; 257/E21.413; 257/E21.09

(57) ABSTRACT

A thin film transistor device and method of making the same are provided. The thin film transistor device includes a crystalline semiconductor layer and a patterned heavily doped semiconductor layer. The patterned heavily doped semiconductor layer includes a first heavily doped semiconductor layer and a second heavily doped semiconductor layer. The first heavily doped semiconductor layer covers a first side surface and a portion of a top surface of the crystalline semiconductor layer; the second heavily doped semiconductor layer covers a second side surface and a portion of the top surface of the crystalline semiconductor layer.

### BACKGROUND OF THE INVENTION

1. Field of the Invention

The present invention relates to a thin film transistor device and a method of making the same, and more particularly to a thin film transistor device including a patterned heavily doped semiconductor layer covering a side surface of a crystalline semiconductor layer and a portion of a top surface, and a method of making the above thin film transistor device.

2. Description of the Prior Art

Amorphous silicon thin film has been widely applied in present flat display devices as the semiconductor layer of the thin film transistor device (a thin film transistor device with its semiconductor layer made of amorphous silicon is often referred to as an amorphous thin film transistor device). However, the low electron mobility, low driving current and poor reliability, set limitations for the amorphous thin film transistor device in actual application. For example, amorphous thin films exhibit a Staebler-Wronski effect when exposed to lights, causing instability of the device as well as failing to meet the requirements of high end liquid crystal display devices. Furthermore, when the amorphous thin film transistor device is applied in an organic electroluminescent display device, the amorphous thin film transistor device is deteriorated after a long term service, causing reduction of the electric current of the organic electroluminescent layer, thereby affecting the brightness of the light luminance. The semiconductor layer made of polycrystalline silicon thin film not only has better electron mobility, but also resolves the problem of deterioration.

The heavily doped drain and source electrodes (also known as the ohmic contact layer) of the polycrystalline silicon thin film transistor of conventional display panels are primarily formed by the ion implantation process; however, the ion implantation process is limited by the size of the ion implantation facility such that the ion implantation facility is only available to small substrates (substrates of the 4.5^{th} or 4^{th} generation or those earlier than the 4.5^{th} or 4^{th} generation). Currently, the ion implantation facility for large substrates does not exist. Also, the ion implantation process and the standard manufacturing processes of amorphous silicon thin film transistor devices are not compatible with each other, restricting the manufacturing process of the polycrystalline silicon thin film transistor device.

### SUMMARY OF THE INVENTION

It is one of the objectives of the present invention to provide a thin film transistor device and a method of making the same, to solve the problems faced by the conventional techniques.

A preferred embodiment in accordance to the present invention provides a thin film transistor device, including a substrate, a crystalline semiconductor layer, a patterned heavily doped semiconductor layer, a source electrode and a drain electrode, a gate insulation layer, and a gate electrode. The crystalline semiconductor layer is disposed on the substrate, and the crystalline semiconductor layer includes a top surface, a first side surface and a second side surface. The patterned heavily doped semiconductor layer is disposed on the crystalline semiconductor layer and the substrate, and the patterned heavily doped semiconductor layer includes a first heavily doped semiconductor layer and a second heavily doped semiconductor layer. The first heavily doped semiconductor layer covers the first side surface and a portion of the top surface connecting with the first side surface of the crystalline semiconductor layer, and the second heavily doped semiconductor layer covers the second side surface and a portion of the top surface connecting with the second side surface of the crystalline semiconductor layer. The source electrode and the drain electrode are disposed on the first heavily doped semiconductor layer and the second heavily doped semiconductor layer respectively. The gate insulation layer is disposed on the source electrode, the drain electrode and the crystalline semiconductor layer. The gate electrode is disposed on the gate insulation layer.

Another preferred embodiment in accordance to the present invention provides a method of forming a thin film transistor device, including the following steps. First a substrate is provided, and a crystalline semiconductor layer is formed on the substrate. Next, a heavily doped semiconductor layer is deposited on the crystalline semiconductor layer and the substrate, and the heavily doped semiconductor layer is patterned to form a first heavily doped semiconductor layer and a second heavily doped semiconductor layer. Then, a source electrode and a drain electrode are formed on the first heavily doped semiconductor layer and the second heavily doped semiconductor layer respectively.

Another preferred embodiment in accordance to the present invention provides a method of forming a thin film transistor device, including the following steps. First a substrate is provided, and a crystalline semiconductor layer is formed on the substrate. Next a heavily doped semiconductor layer is deposited on the crystalline semiconductor layer and the substrate. Then, a conductive layer is formed on the heavily doped semiconductor layer. Subsequently, the conductive layer is patterned to form a source electrode and a drain electrode, and the heavily doped semiconductor layer is patterned to form a first heavily doped semiconductor layer and a second heavily doped semiconductor layer.

The first side surface and the second side surface of the crystalline semiconductor layer of the thin film transistor device of the present invention are covered by the first heavily doped semiconductor layer and the second heavily doped semiconductor layer respectively. Since the heavily doped semiconductor layer can block the electron hole from migrating, the problem of current leakage can be avoided. Also, the thin film transistor device manufacturing method of the present invention uses a deposition process to form the heavily doped semiconductor layer instead of using an ion implantation process to form the heavily doped semiconductor layer, so that the manufacturing process is not limited by the size of the substrate, and the deposition process can be integrated into the standard manufacturing process of the amorphous silicon thin film transistor device.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 4 are schematic diagrams illustrating a method of forming a thin film transistor device in accordance to a preferred embodiment of the present invention.

FIG. 5 to FIG. 8 are schematic diagrams illustrating a method of forming a thin film transistor device in accordance to another preferred embodiment of the present invention.

### DETAILED DESCRIPTION

To provide a better understanding of the present invention, preferred embodiments will be detailed as follows. The preferred embodiments of the present invention are illustrated in the accompanying drawings with numbered elements to elaborate the contents and effects to be achieved.

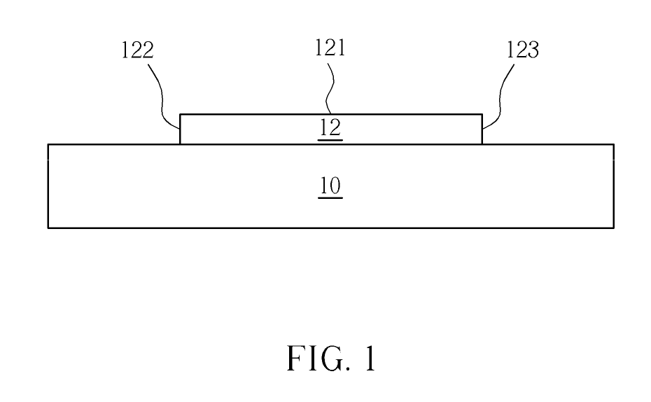

Referring to FIG. 1 to FIG. 4, FIG. 1 to FIG. 4 are schematic diagrams illustrating a method of forming a thin film transistor device in accordance to a preferred embodiment of the present invention. As illustrated in FIG. 1, first a substrate 10 is provided and the substrate 10 may be a transparent substrate, e.g. a glass substrate, but is not limited. The substrate 10 may as well be other types of substrates, e.g. a plastic substrate or a wafer. Next a crystalline semiconductor layer 12 is formed on the substrate 10. Before the formation of the crystalline semiconductor layer 12, a buffer layer (not illustrated in the figure) may be optionally formed on the substrate 10. The crystalline semiconductor layer 12 in accordance to the present embodiment is a polycrystalline silicon semiconductor layer, but the material for the crystalline semiconductor layer 12 is not limited to silicon and the material for the crystalline semiconductor layer 12 can be other semiconductor materials. Also, the crystallization of the crystalline semiconductor layer 12 is not limited to polycrystalline, and the crystallization of the crystalline semiconductor layer 12 may be other types of crystallization, e.g. microcrystalline type. The method of forming the crystalline semiconductor layer 12 includes the following steps: forming an amorphous silicon semiconductor layer on the substrate 10; performing a phase transformation process which transforms the amorphous silicon semiconductor layer into the crystalline semiconductor layer 12 (polycrystalline silicon semiconductor layer in this embodiment); and patterning the crystalline semiconductor layer 12, e.g. using a photolithography and etching process. In accordance to the present embodiment, the phase transformation process is a solid phase crystallization (SPC) process which transforms the amorphous silicon to polycrystalline silicon at a high temperature approximately between 600° C. and 700° C. Under such high temperature, the substrate 10 is contracted inevitably; therefore, the thin film transistor device in accordance to the present embodiment is a top-gate type thin film transistor device. In the formation of a top-gate type thin film transistor device, a source electrode, a drain electrode and a gate electrode are sequentially formed after the formation of the polycrystalline silicon semiconductor layer by the high temperature solid phase crystallization process, and thus misalignments between the source electrode, the drain electrode and the gate electrode can be avoided. It is to be noted that, the phase transformation process in accordance to the present embodiment is not limited to the solid state crystallization process and the phase transformation process may be other types of phase transformation processes, e.g. rapid thermal process (RTP), furnace heating process, excimer laser annealing (ELA) process, metal-induced crystallization (MIC) process, metal-induced lateral crystallization (MILC) process, sequential lateral solidification (SLS) process, continuous grain silicon (CGS) process, or other types of phase transformation processes. Furthermore, the method in accordance to the present embodiment is not limited to forming the crystalline semiconductor layer 12 under the phase transformation process, e.g. the crystalline semiconductor layer 12 may be formed on the substrate 10 directly and then the crystalline semiconductor layer 12 is patterned. The crystalline semiconductor layer 12 after the patterning process includes a top surface 121, a first side surface 122 and a second side surface 123.

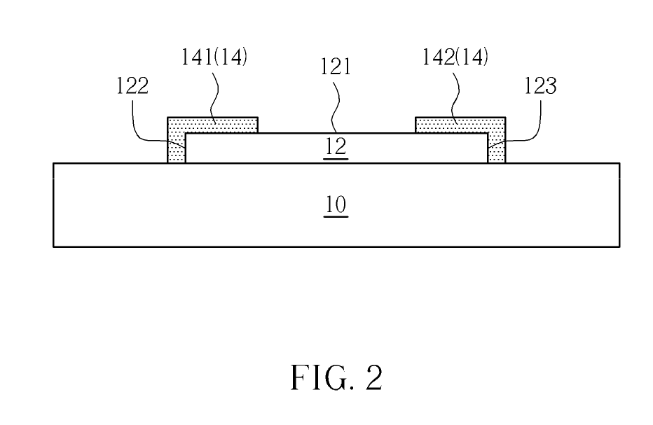

As illustrated in FIG. 2, a heavily doped semiconductor layer 14 (e.g. an N type heavily doped semiconductor layer) is then deposited on the crystalline semiconductor layer 12 and the substrate 10, and the heavily doped semiconductor layer 14 is patterned to form a first heavily doped semiconductor layer 141 and a second heavily doped semiconductor layer 142. The heavily doped semiconductor layer 14, for example, may be formed by a chemical vapor deposition process, and the patterning step of the heavily doped semiconductor layer 14 can be achieved by a photolithography and etching process with a photomask incorporated. The first heavily doped semiconductor layer 141 and the second heavily doped semiconductor layer 142 are corresponding to two sides of the crystalline semiconductor layer 12 respectively, the first heavily doped semiconductor layer 141 covers the first side surface 122 of the crystalline semiconductor layer 12 and a portion of the top surface 121 connecting with the first side surface 122, and the second heavily doped semiconductor layer 142 covers the second side surface 123 of the crystalline semiconductor layer 12 and a portion of the top side surface 121 connecting with the second side surface 123.

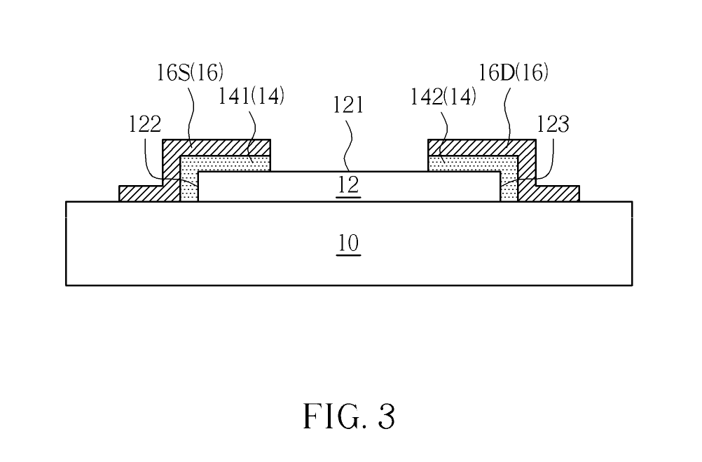

As illustrated in FIG. 3, a conductive layer 16, e.g. a metallic layer, is formed on the substrate 10, the crystalline semiconductor layer 12 and the heavily doped semiconductor layer 14. The conductive layer 16 is then patterned, for example using a photolithography and etching process with a photomask incorporated, to form a source electrode 16S and a drain electrode 16D. In accordance to the present embodiment, the source electrode 16S is substantially positioned on the first heavily doped semiconductor layer 141 and the source electrode 16S does not contact the crystalline semiconductor layer 12. In addition, the source electrode 16S protrudes from the first heavily doped semiconductor layer 141 and the source electrode 16S covers a portion of the substrate 10. The drain electrode 16D is substantially positioned on the second heavily doped semiconductor layer 142 and the drain electrode 16D does not contact the crystalline semiconductor layer 12. In addition, the drain electrode 16D protrudes from the second heavily doped semiconductor layer 142 and the drain electrode 16D covers a portion of the substrate 10. As illustrated in FIG. 3, the first side surface 122 of the crystalline semiconductor layer 12 and the second side surface 123 of the crystalline semiconductor layer 12 are covered by the first heavily doped semiconductor layer 141 and the second heavily doped semiconductor layer 142 respectively. Therefore, the first heavily doped semiconductor layer 141 is disposed between the source electrode 16S and the first side surface 122 of the crystalline semiconductor layer 12, and the second heavily doped semiconductor layer 142 is disposed between the drain electrode 16D and the second side surface 123 of the crystalline semiconductor layer 12, such that the first heavily doped semiconductor layer 141 and the second heavily doped semiconductor layer 142 can block the electron holes from migrating and avoid a current leakage between the source electrode 16S/the drain electrode 16D and the crystalline semiconductor layer 12.

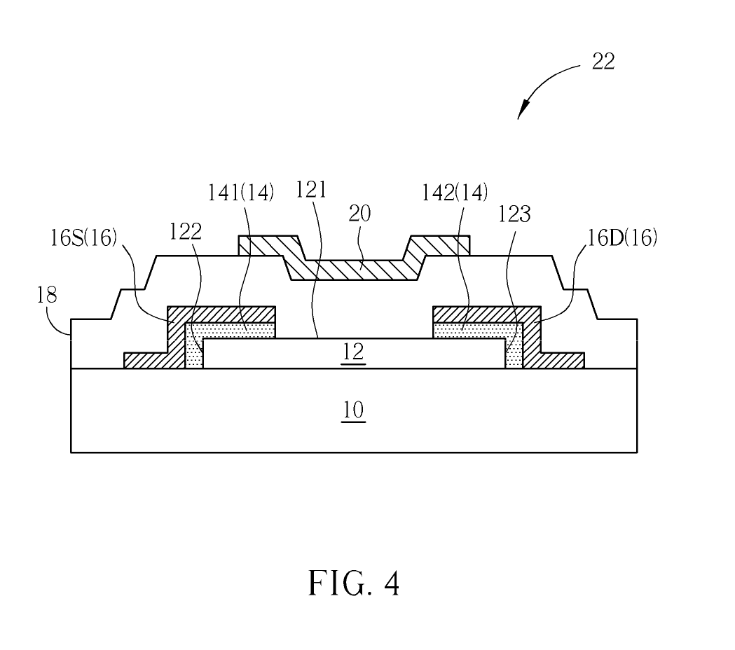

As illustrated in FIG. 4, a gate insulation layer 18 is then formed on the substrate 10, the crystalline semiconductor layer 12, the source electrode 16S and the drain electrode 16D. Next, a gate electrode 20 corresponding to the crystalline semiconductor layer 12 is formed on the gate insulation layer 18 to form the thin film transistor device 22 of the present embodiment.

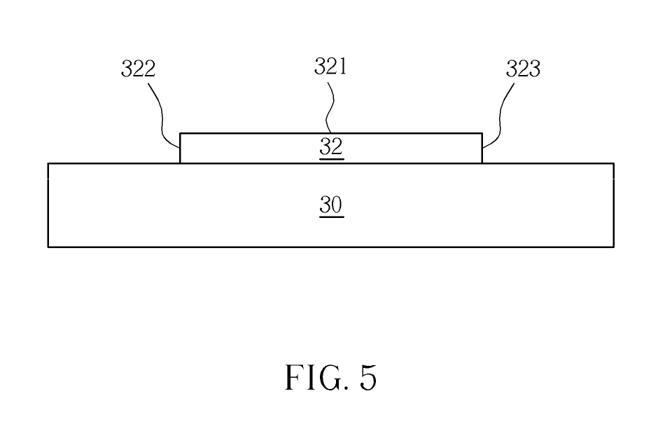

Referring to FIG. 5 to FIG. 8, FIG. 5 to FIG. 8 are schematic diagrams illustrating a method of forming a thin film transistor device in accordance to another preferred embodiment of the present invention. To simplify the description and for the convenience of comparison between each of the embodiments of the present invention, only the differences are illustrated, and repeated descriptions are not redundantly given. As illustrated in FIG. 5, a substrate 30 is first provided. Next a crystalline semiconductor layer 32 is formed on the substrate 30, and the crystalline semiconductor layer 32 is then patterned. After the patterning process, the crystalline semiconductor layer 32 includes a top surface 321, a first side surface 322 and a second side surface 323.

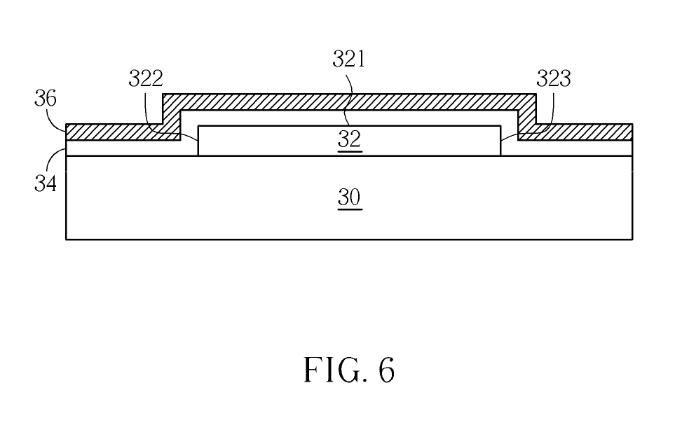

As illustrated in FIG. 6, a heavily doped semiconductor layer 34 and a conductive layer 36 are sequentially formed on the crystalline semiconductor layer 32 and the substrate 30. The heavily doped semiconductor layer 34 may be formed by a chemical vapor deposition process, and the conductive layer 36 may be made of a metallic layer or other conductive layers of excellent electrical conductivities.

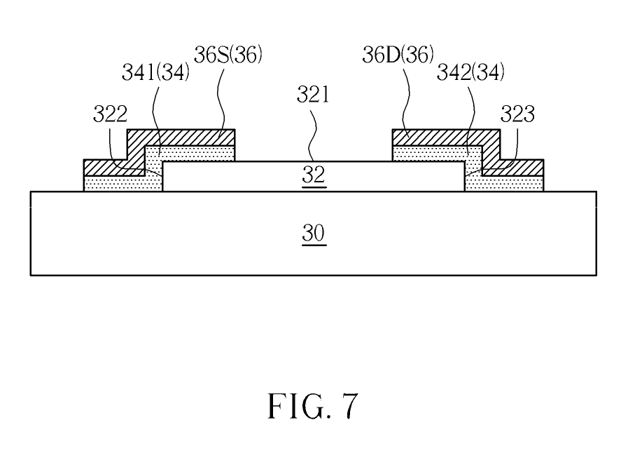

As illustrated in FIG. 7, the heavily doped semiconductor layer 34 is patterned to form a first heavily doped semiconductor layer 341 and a second heavily doped semiconductor layer 342. The conductive layer 36 is patterned to form a source electrode 36S and a drain electrode 36D. In accordance to the present embodiment, the heavily doped semiconductor layer 34 and the conductive layer 36 are patterned by a same photomask, so that the manufacturing process is simplified, but is not limited. For instance, the heavily doped semiconductor layer 34 and the conductive layer 36 may also be patterned using different photomasks or patterned individually using other methods. The first heavily doped semiconductor layer 341 and the second heavily doped semiconductor layer 342 are corresponding to two sides of the crystalline semiconductor layer 32 respectively. The first heavily doped semiconductor layer 341 covers the first side surface 322 of the crystalline semiconductor layer 32 and a portion of the top surface 321 connecting with the first side surface 322, and the first heavily doped semiconductor layer 341 also covers a portion of the substrate 30. The second heavily doped semiconductor layer 342 covers the second side surface 323 of the crystalline semiconductor layer 32 and a portion of the top surface 321 connecting the second side surface 323, and the second heavily doped semiconductor layer 342 also covers a portion of the substrate 30. Furthermore, in accordance to the present embodiment, a fringe of the source electrode 36S is substantially aligned to a fringe of the first heavily doped semiconductor layer 341, and a fringe of the drain electrode 36D is substantially aligned to a fringe of the second heavily doped semiconductor layer 342. According to FIG. 7, the first side surface 322 of the crystalline semiconductor layer 32 and the second side surface 323 of the crystalline semiconductor layer 32 are covered by the first heavily doped semiconductor layer 341 and the second heavily doped semiconductor layer 342 respectively. Therefore, the first heavily doped semiconductor layer 341 is disposed between the source electrode 36S and the first side surface 322 of the crystalline semiconductor layer 32, and the second heavily doped semiconductor layer 342 is disposed between the drain electrode 36D and the second side surface 323 of the crystalline semiconductor layer 32, such that the first heavily doped semiconductor layer 341 and the second heavily doped semiconductor layer 342 can block the electron holes from migrating which avoids the problem of current leakage.

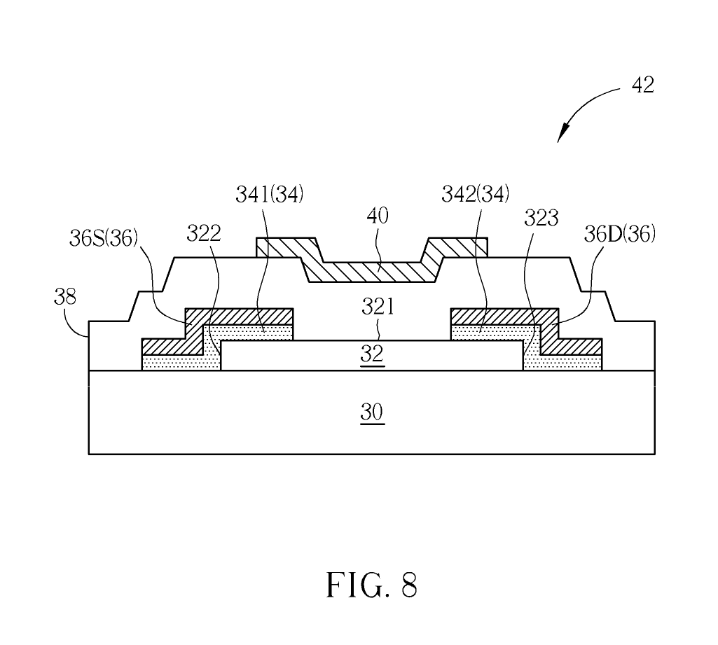

As illustrated in FIG. 8, a gate insulation layer 38 is formed on the substrate 30, the crystalline semiconductor layer 32, the source electrode 36S and the drain electrode 36D. Then a gate electrode 40 corresponding to the crystalline semiconductor layer 32 is formed on the gate insulation layer 38 to form the thin film transistor device 42 of the present embodiment.

In summary, the first side surface and the second side surface of the crystalline semiconductor layer of the thin film transistor device in accordance to the present invention are covered by the first heavily doped semiconductor layer and the second heavily doped semiconductor layer respectively. Since the heavily doped semiconductor layer can block the electron holes from migrating, the problem of current leakage is avoided. Furthermore, the method of forming the thin film transistor device in accordance to the present invention uses a chemical vapor deposition process to form a heavily doped semiconductor layer instead of using an ion implantation process to form a heavily doped semiconductor layer, the manufacturing process is therefore not limited to the size of the substrate, and the deposition process can be integrated into the standard manufacturing process of the amorphous silicon thin film transistor device. Moreover, the thin film transistor device in accordance to the present invention is a top-gate type thin film transistor device so that even when the crystalline semiconductor layer is formed by a high temperature phase transformation process, misalignments between the source electrode, the drain electrode and the gate electrode are avoided. In addition, the thin film transistor device in accordance to the present invention utilizes crystalline semiconductor layer as a channel, and thus the thin film transistor device has characteristics such as high electron mobility, high driving current and high reliability. Accordingly, the thin film transistor device in accordance to the present invention may be applied in products such as high end liquid crystal display devices or organic electroluminescent display devices.

Those skilled in the art will readily observe that numerous modifications and alterations of the device and method may be made while retaining the teachings of the invention.

What is claimed is:

1. A thin film transistor device, comprising:
a substrate;
a crystalline semiconductor layer disposed on the substrate, wherein the crystalline semiconductor layer comprises a top surface, a first side surface and a second side surface;
a patterned heavily doped semiconductor layer disposed on the crystalline semiconductor layer and the substrate, the patterned heavily doped semiconductor layer comprising a first heavily doped semiconductor layer and a second heavily doped semiconductor layer, wherein the first heavily doped semiconductor layer covers the first side surface and a portion of the top surface connecting with the first side surface of the crystalline semiconductor layer, and the second heavily doped semiconductor layer covers the second side surface and a portion of the top surface connecting with the second side surface of the crystalline semiconductor layer;
a source electrode and a drain electrode, respectively disposed on the first heavily doped semiconductor layer and the second heavily doped semiconductor layer;
a gate insulation layer disposed on the source electrode, the drain electrode and the crystalline semiconductor layer; and
a gate electrode disposed on the gate insulation layer.

2. The thin film transistor device of claim 1, wherein the crystalline semiconductor layer comprises a polycrystalline silicon semiconductor layer.

3. The thin film transistor device of claim 1, wherein the first heavily doped semiconductor layer further covers a portion of the substrate, and the second heavily doped semiconductor layer further covers a portion of the substrate.

4. The thin film transistor device of claim 3, wherein a fringe of the source electrode is substantially aligned to a fringe of the first heavily doped semiconductor layer, and a fringe of the drain electrode is substantially aligned to a fringe of the second heavily doped semiconductor layer.

5. The thin film transistor device of claim 1, wherein the source electrode protrudes from the first heavily doped semiconductor layer and the source electrode covers a portion of the substrate, and the drain electrode protrudes from the second heavily doped semiconductor layer and the drain electrode covers a portion of the substrate.

6. A method of forming the thin film transistor device, comprising:
providing a substrate;
forming a crystalline semiconductor layer on the substrate;
depositing a heavily doped semiconductor layer on the crystalline semiconductor layer and the substrate, and patterning the heavily doped semiconductor layer to form a first heavily doped semiconductor layer and a second heavily doped semiconductor layer; and
forming a source electrode and a drain electrode on the first heavily doped semiconductor layer and the second heavily doped semiconductor layer respectively.

7. The method of claim 6, wherein the crystalline semiconductor layer comprises a polycrystalline silicon semiconductor layer.

8. The method of claim 6, wherein the crystalline semiconductor layer comprises a top surface, a first side surface and a second side surface, the first heavily doped semiconductor layer covers the first side surface and a portion of the top surface connecting with the first side surface of the crystalline semiconductor layer, and the second heavily doped semiconductor layer covers the second side surface and a portion of the top surface connecting with the second side surface of the crystalline semiconductor layer.

9. The method of claim 8, wherein the first heavily doped semiconductor layer further covers a portion of the substrate, and the second heavily doped semiconductor layer further covers a portion of the substrate.

10. The method of claim 9, wherein a fringe of the source electrode is substantially aligned to a fringe of the first heavily doped semiconductor layer, and a fringe of the drain electrode is substantially aligned to a fringe of the second heavily doped semiconductor layer.

11. The method of claim 8, wherein the source electrode protrudes from the first heavily doped semiconductor layer and the source electrode covers a portion of the substrate, and the drain electrode protrudes from the second heavily doped semiconductor layer and the drain electrode covers a portion of the substrate.

12. The method of claim 6, further comprising sequentially forming a gate insulation layer and a gate electrode on the crystalline semiconductor layer, the source electrode and the drain electrode.

13. A method of forming the thin film transistor device, comprising:
providing a substrate;
forming a crystalline semiconductor layer on the substrate;
depositing a heavily doped semiconductor layer on the crystalline semiconductor layer and the substrate;
forming a conductive layer on the heavily doped semiconductor layer;
patterning the conductive layer to form a source electrode and a drain electrode, and patterning the heavily doped semiconductor layer to form a first heavily doped semiconductor layer and a second heavily doped semiconductor layer.

14. The method of claim 13, wherein the source electrode, the drain electrode, the first heavily doped semiconductor layer and the second heavily doped semiconductor layer are patterned by a same photomask.

15. The method of claim 13, wherein the crystalline semiconductor layer comprises a polycrystalline silicon semiconductor layer.

16. The method of claim 13, wherein the crystalline semiconductor layer comprises a top surface, a first side surface and a second side surface, the first heavily doped semiconductor layer covers the first side surface and a portion of the top surface connecting with the first side surface of the crystalline semiconductor layer, and the second heavily doped semiconductor layer covers the second side surface and a portion of the top surface connecting with the second side surface of the crystalline semiconductor layer.

17. The method of claim 16, wherein the first heavily doped semiconductor layer further covers a portion of the substrate, and the second heavily doped semiconductor layer further covers a portion of the substrate.

18. The method of claim 17, wherein a fringe of the source electrode is substantially aligned to a fringe of the first heavily doped semiconductor layer, and a fringe of the drain electrode is substantially aligned to a fringe of the second heavily doped semiconductor layer.

19. The method of claim 13, wherein the source electrode protrudes from the first heavily doped semiconductor layer and the source electrode covers a portion of the substrate, and the drain electrode protrudes from the second heavily doped semiconductor layer and the drain electrode covers a portion of the substrate.
